(19) United States
(12) Patent Application Publication
(10) Pub. No.: US 2026/0106596 A1
(43) Pub. Date: Apr. 16, 2026

(54) ACOUSTIC WAVE DEVICE WITH IMPROVED QUALITY FACTOR

(71) Applicant: SKYWORKS SOLUTIONS, INC., Irvine, CA (US)

(72) Inventors: Yiliu Wang, Irvine, CA (US); Motoyuki Tajima, Yokohama-Shi (JP)

(21) Appl. No.: 19/256,318

(22) Filed: Jul. 1, 2025

Related U.S. Application Data
(60) Provisional application No. 63/666,764, filed on Jul. 2, 2024.

(51) Int. Cl. H03H 9/13; H01Q 1/27; H03H 9/54

(52) U.S. Cl. CPC H03H 9/133; H01Q 1/27; H03H 9/54

(57) ABSTRACT

Aspects and embodiments disclosed herein include an acoustic wave device comprising a substrate and a pair of interdigital transducer (IDT) electrodes disposed on the substrate. Each of the IDT electrodes include a bus bar and a plurality of fingers extending from the bus bar along a first direction perpendicular to a propagation direction of a main acoustic wave, a respective finger of one IDT electrode arranged interleaved with respective fingers of the other IDT electrode. At least one IDT capacitor is disposed on the substrate and apart from the pair of IDT electrodes along the first direction. The at least one IDT capacitor has a width in the first direction less than a predetermined value such to control a frequency response of the at least one IDT capacitor in a range below a resonance frequency of the at least one IDT capacitor.

### CROSS-REFERENCE TO RELATED APPLICATIONS

This application claims priority under 35 U.S.C. § 119(e) to U.S. Provisional Patent Application Ser. No. 63/666,764, titled “ACOUSTIC WAVE DEVICE WITH IMPROVED QUALITY FACTOR,” filed Jul. 2, 2024, the entire content of which is incorporated herein by reference for all purposes.

### BACKGROUND

### Field

Aspects and embodiments disclosed herein relate to electronic systems, and in particular, to an acoustic wave device for use in radio frequency (RF) electronics.

### Description of Related Technology

Filters are used in radio frequency (RF) communication systems to allow signals to pass through at discreet frequencies and to reject signals at frequencies outside of a specified range. An acoustic wave filter, which is used widely in the wireless communication field, can include a plurality of resonators arranged to filter a radio frequency signal. Example acoustic wave filters include surface acoustic wave (SAW) filters and/or bulk acoustic wave (BAW) filters. A film bulk acoustic wave resonator filter is an example of a BAW filter. Acoustic wave filters can be implemented in radio frequency electronic systems. For instance, filters in a radio frequency front end of a mobile phone can include acoustic wave filters. A plurality of acoustic wave filters can be arranged as a multiplexer. For example, two surface acoustic wave filters can be arranged as a duplexer.

Examples of RF communication systems with one or more filter modules include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### SUMMARY

In accordance with one aspect, there is provided an acoustic wave device. The acoustic wave device comprises a substrate, a pair of interdigital transducer (IDT) electrodes disposed on the substrate, each of the IDT electrodes including a bus bar and a plurality of fingers extending from the bus bar along a first direction perpendicular to a propagation direction of a main acoustic wave, a respective finger of one IDT electrode arranged interleaved with respective fingers of the other IDT electrode, and at least one IDT capacitor disposed on the substrate and apart from the pair of IDT electrodes along the first direction, the at least one IDT capacitor having a width in the first direction less than a predetermined value such to control a frequency response of the at least one IDT capacitor in a range below a resonance frequency of the at least one IDT capacitor.

In some embodiments, the at least one IDT capacitor includes a pair of bus bars extending along a second direction parallel to the propagation direction of the main acoustic wave.

In some embodiments, the at least one IDT capacitor includes a predefined number of fingers extending from respective bus bars along the first direction.

In some embodiments, the at least one IDT capacitor includes a pair of bus bars extending along the first direction.

In some embodiments, the at least one IDT capacitor includes a predefined number of fingers extending from respective bus bars along a second direction parallel to the propagation direction of the main acoustic wave.

In some embodiments, the acoustic wave device further comprises reflectors formed on the substrate, one of the reflectors being adjacent to one side of the pair of IDT electrodes and another reflector being adjacent to an opposite side of the pair of IDT electrodes so as to interpose the pair of IDT electrodes therebetween, the reflectors and the pair of IDT electrodes arranged along a second direction parallel to the propagation direction of the main acoustic wave.

In some embodiments, the at least one IDT capacitor includes a pair of bus bars extending along the first direction.

In some embodiments, the at least one IDT capacitor includes a predefined number of fingers extending from respective bus bars along a second direction parallel to the propagation direction of the main acoustic wave.

In accordance with another aspect, there is provided an acoustic wave device. The acoustic wave device comprises a substrate, a pair of interdigital transducer (IDT) electrodes disposed on the substrate, each of the IDT electrodes including a bus bar and a plurality of fingers extending from the bus bar along a first direction perpendicular to a propagation direction of a main acoustic wave, a respective finger of one IDT electrode arranged interleaved with respective fingers of the other IDT electrode, and at least one IDT capacitor disposed apart from the pair of IDT electrodes along the first direction, the at least one IDT capacitor including a pair of bus bars arranged along the first direction.

In some embodiments, the at least one IDT capacitor includes a plurality of fingers extending from respective bus bars along a second direction parallel to the propagation direction of the main acoustic wave.

In some embodiments, the at least one IDT capacitor has a width in the first direction less than a predetermined value.

In some embodiments, the acoustic wave device further comprises reflectors formed on the substrate, one of the reflectors being adjacent to one side of the pair of IDT electrodes and another reflector being adjacent to an opposite side of the pair of IDT electrodes so as to interpose the pair of IDT electrodes therebetween, the reflectors and the pair of IDT electrodes arranged along a second direction parallel to the propagation direction of the main acoustic wave.

In accordance with another aspect, there is provided a radio frequency module. The radio frequency module comprises a packaging substrate configured to receive a plurality of components, and an acoustic wave device implemented on the packaging substrate, the acoustic wave device including a substrate, a pair of interdigital transducer (IDT) electrodes disposed on the substrate, each of the IDT electrodes including a bus bar and a plurality of fingers extending from the bus bar along a first direction perpendicular to a propagation direction of a main acoustic wave, a respective finger of one IDT electrode arranged interleaved with respective fingers of the other IDT electrode, and at least one IDT capacitor disposed on the substrate and apart from the pair of IDT electrodes along the first direction, the at least one IDT capacitor having a width in the first direction less than a predetermined value such to control a frequency response of the at least one IDT capacitor in a range below a resonance frequency of the at least one IDT capacitor.

In some embodiments, the radio frequency module is a front-end module.

In some embodiments, the at least one IDT capacitor includes a pair of bus bars extending along a second direction parallel to the propagation direction of the main acoustic wave.

In some embodiments, the at least one IDT capacitor includes a predefined number of fingers extending from respective bus bars along the first direction.

In some embodiments, the at least one IDT capacitor includes a pair of bus bars extending along the first direction.

In some embodiments, the at least one IDT capacitor includes a predefined number of fingers extending from respective bus bars along a second direction parallel to the propagation direction of the main acoustic wave.

In some embodiments, the acoustic wave device further includes reflectors formed on the substrate, one of the reflectors being adjacent to one side of the pair of IDT electrodes and another reflector being adjacent to an opposite side of the pair of IDT electrodes so as to interpose the pair of IDT electrodes therebetween, the reflectors and the pair of IDT electrodes arranged along a second direction parallel to the propagation direction of the main acoustic wave.

In accordance with another aspect, there is provided a radio frequency module. The radio frequency module comprises a packaging substrate configured to receive a plurality of components, and an acoustic wave device implemented on the packaging substrate, the acoustic wave device including a substrate, a pair of interdigital transducer (IDT) electrodes disposed on the substrate, each of the IDT electrodes including a bus bar and a plurality of fingers extending from the bus bar along a first direction perpendicular to a propagation direction of a main acoustic wave, a respective finger of one IDT electrode arranged interleaved with respective fingers of the other IDT electrode, and at least one IDT capacitor disposed apart from the pair of IDT electrodes along the first direction, the at least one IDT capacitor including a pair of bus bars arranged along the first direction.

In some embodiments, the radio frequency module is a front-end module.

In some embodiments, the at least one IDT capacitor includes a plurality of fingers extending from respective bus bars along a second direction parallel to the propagation direction of the main acoustic wave.

In some embodiments, the at least one IDT capacitor having a width in the first direction less than a predetermined value.

In some embodiments, the acoustic wave device further includes reflectors formed on the substrate, one of the reflectors being adjacent to one side of the pair of IDT electrodes and another reflector being adjacent to an opposite side of the pair of IDT electrodes so as to interpose the pair of IDT electrodes therebetween, the reflectors and the pair of IDT electrodes arranged along a second direction parallel to the propagation direction of the main acoustic wave.

In accordance with another aspect, there is provided a mobile device. The mobile device comprises an antenna configured to receive a radio frequency signal, and a front end system configured to communicate with the antenna, the front end system including an acoustic wave device including a substrate, a pair of interdigital transducer (IDT) electrodes disposed on the substrate, each of the IDT electrodes including a bus bar and a plurality of fingers extending from the bus bar along a first direction perpendicular to a propagation direction of a main acoustic wave, a respective finger of one IDT electrode arranged interleaved with respective fingers of the other IDT electrode, and at least one IDT capacitor disposed on the substrate and apart from the pair of IDT electrodes along the first direction, the at least one IDT capacitor having a width in the first direction less than a predetermined value such to control a frequency response of the at least one IDT capacitor in a range below a resonance frequency of the at least one IDT capacitor.

In some embodiments, the at least one IDT capacitor includes a pair of bus bars extending along a second direction parallel to the propagation direction of the main acoustic wave.

In some embodiments, the at least one IDT capacitor includes a predefined number of fingers extending from respective bus bars along the first direction.

In some embodiments, wherein the at least one IDT capacitor includes a pair of bus bars extending along the first direction.

In some embodiments, the at least one IDT capacitor includes a predefined number of fingers extending from respective bus bars along a second direction parallel to the propagation direction of the main acoustic wave.

In some embodiments, the acoustic wave device further includes reflectors formed on the substrate, one of the reflectors being adjacent to one side of the pair of IDT electrodes and another reflector being adjacent to an opposite side of the pair of IDT electrodes so as to interpose the pair of IDT electrodes therebetween, the reflectors and the pair of IDT electrodes arranged along a second direction parallel to the propagation direction of the main acoustic wave.

In accordance with another aspect, there is provided a mobile device. The mobile device comprises an antenna configured to receive a radio frequency signal, and a front end system configured to communicate with the antenna, the front end system including an acoustic wave device including a substrate, a pair of interdigital transducer (IDT) electrodes disposed on the substrate, each of the IDT electrodes including a bus bar and a plurality of fingers extending from the bus bar along a first direction perpendicular to a propagation direction of a main acoustic wave, a respective finger of one IDT electrode arranged interleaved with respective fingers of the other IDT electrode, and at least one IDT capacitor disposed apart from the pair of IDT electrodes along the first direction, the at least one IDT capacitor including a pair of bus bars arranged along the first direction.

In some embodiments, the at least one IDT capacitor includes a plurality of fingers extending from respective bus bars along a second direction parallel to the propagation direction of the main acoustic wave.

In some embodiments, the at least one IDT capacitor has a width in the first direction less than a predetermined value.

In some embodiments, the acoustic wave device further includes reflectors formed on the substrate, one of the reflectors being adjacent to one side of the pair of IDT electrodes and another reflector being adjacent to an opposite side of the pair of IDT electrodes so as to interpose the pair of IDT electrodes therebetween, the reflectors and the pair of IDT electrodes arranged along a second direction parallel to the propagation direction of the main acoustic wave.

### BRIEF DESCRIPTION OF THE DRAWINGS

FIG. 1 is a schematic diagram of one embodiment of a mobile device;

FIG. 2A is a schematic diagram of a carrier aggregation system;

FIG. 2B is a schematic diagram of a carrier aggregation system;

FIG. 2C is a schematic diagram of a carrier aggregation system;

FIG. 2D is a schematic diagram of a carrier aggregation system;

FIG. 3A is a schematic block diagram of a module that includes a filter;

FIG. 3B is a schematic block diagram of a module that includes a filter;

FIG. 4 is an example schematic diagram of an acoustic wave device;

FIG. 5 is a sectional view of the acoustic wave device of FIG. 4 aligned along a single electrode finger;

FIG. 6 is a schematic diagram of an example of an acoustic wave device according to an embodiment of the present disclosure;

FIG. 7A shows an example of a simulation result of measuring the conductance of interdigital transducer (IDT) capacitors having constant total capacitance;

FIG. 7B shows an example of a simulation result of measuring the conductance of IDT capacitors having different lengths (L) with fixed widths (W);

FIG. 7C shows an example of a simulation result of measuring the conductance of IDT capacitors having different widths (W) with fixed lengths (L);

FIG. 8 is a schematic diagram of an example of an acoustic wave device according to an embodiment of the present disclosure;

FIG. 9A shows an example of a simulation result of measured conductances of IDT capacitors with different measurement methods;

FIG. 9B shows an example of a simulation result of measured conductances of IDT capacitors rotated by 90 degrees with different lengths compared to a non-rotated IDT capacitor;

FIG. 9C shows an example of a simulation result of measured capacitances of IDT capacitors rotated by 90 degrees compared to a non-rotated IDT capacitor;

FIG. 10A is a schematic diagram of one embodiment of a packaged module;

FIG. 10B is a schematic diagram of a cross-section of the packaged module of FIG. 10A taken along the lines 10B-10B; and

FIG. 11 is a schematic diagram of one embodiment of a phone board.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

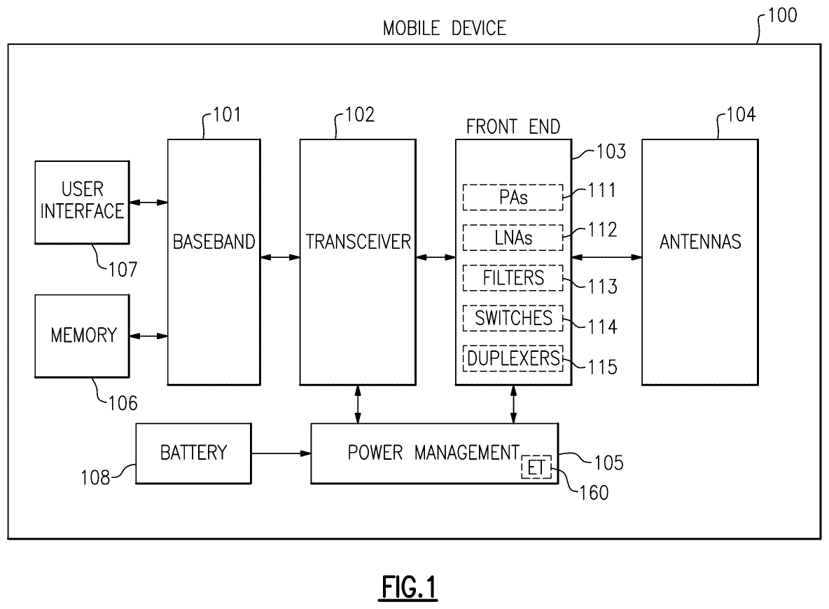

FIG. 1 is a schematic diagram of one example of a mobile device 100. The mobile device 100 includes a baseband system 101, a transceiver 102, a front end system 103, antennas 104, a power management system 105, a memory 106, a user interface 107, and a battery 108.

The mobile device 100 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 102 generates RF signals for transmission and processes incoming RF signals received from the antennas 104. It will be understood that various functionalities associated with the transmission and reception of RF signals can be achieved by one or more components that are collectively represented in FIG. 1 as the transceiver 102. In one example, separate components (for instance, separate circuits or dies) can be provided for handling certain types of RF signals.

The front end system 103 aids in conditioning signals transmitted to and/or received from the antennas 104. In the illustrated embodiment, the front end system 103 includes power amplifiers (PAs) 111, low noise amplifiers (LNAs) 112, filters 113, switches 114, and duplexers 115. However, other implementations are possible.

For example, the front end system 103 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 100 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 104 can include antennas used for a wide variety of types of communications. For example, the antennas 104 can include antennas associated with transmitting and/or receiving signals associated with a wide variety of frequencies and communications standards.

In certain implementations, the antennas 104 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 100 can operate with beamforming in certain implementations. For example, the front end system 103 can include phase shifters having variable phases controlled by the transceiver 102. Additionally, the phase shifters may be controlled to provide beam formation and directivity for transmission and/or reception of signals using the antennas 104. For example, in the context of signal transmission, the phases of the transmit signals provided to the antennas 104 are controlled such that radiated signals from the antennas 104 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 104 from a particular direction. In certain implementations, the antennas 104 include one or more arrays of antenna elements to enhance beamforming.

The baseband system 101 is coupled to the user interface 107 to facilitate processing of various user input and output (I/O), such as voice and data. The baseband system 101 provides the transceiver 102 with digital representations of transmit signals, which the transceiver 102 processes to generate RF signals for transmission. The baseband system 101 also processes digital representations of received signals provided by the transceiver 102. As shown in FIG. 1, the baseband system 101 is coupled to the memory 106 to facilitate operation of the mobile device 100.

The memory 106 can be used for a wide variety of purposes, such as storing data and/or instructions to facilitate the operation of the mobile device 100 and/or to provide storage of user information.

The power management system 105 provides a number of power management functions of the mobile device 100. The power management system 105 of FIG. 1 includes an envelope tracker 160. As shown in FIG. 1, the power management system 105 receives a battery voltage from the battery 108. The battery 108 can be any suitable battery for use in the mobile device 100, including, for example, a lithium-ion battery.

The mobile device 100 of FIG. 1 illustrates one example of an RF communication system that can include power amplifier(s) implemented in accordance with one or more features of the present disclosure. However, the teachings herein are applicable to RF communication systems implemented in a wide variety of ways.

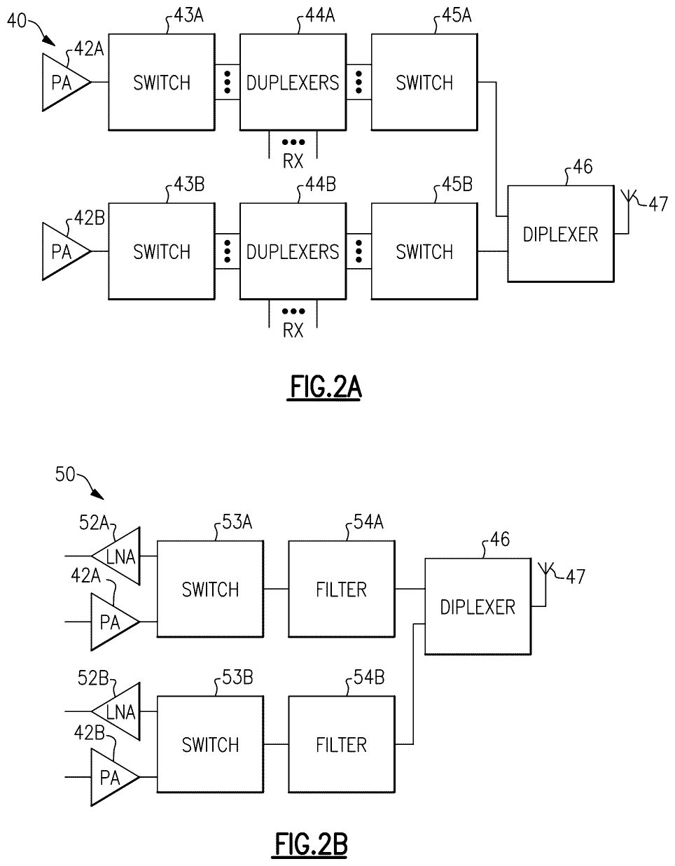

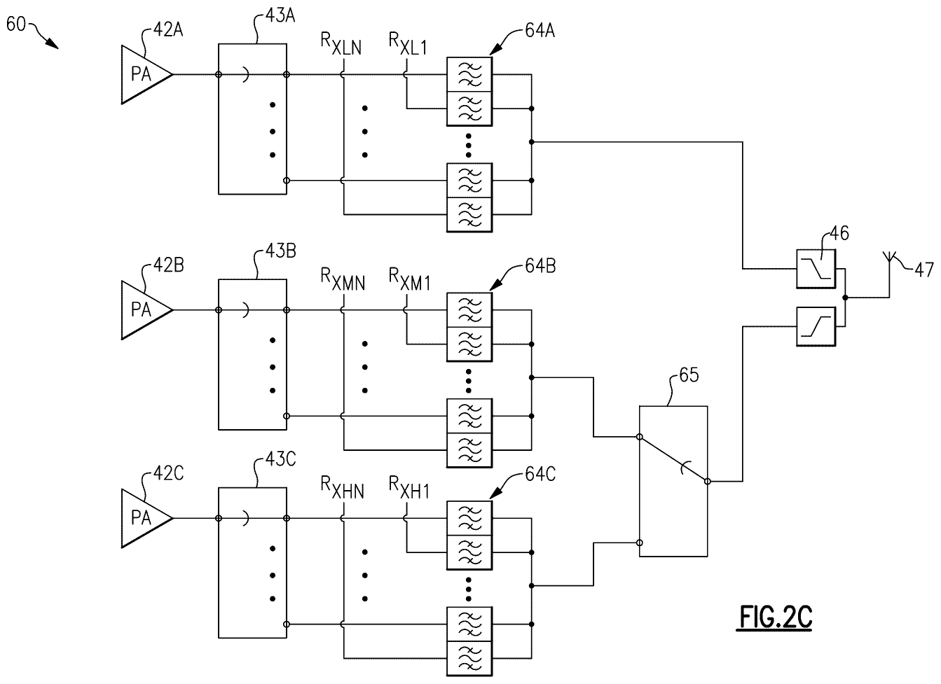

FIG. 2A is a schematic diagram of a carrier aggregation system 40. The illustrated carrier aggregation system 40 includes power amplifiers 42A and 42B, switches 43A and 43B, duplexers 44A and 44B, switches 45A and 45B, diplexer 46, and antenna 47. The power amplifiers 42A and 42B can each transmit an amplified RF signal associated with a different carrier. The switch 43A can be a band select switch. The switch 43A can couple an output of the power amplifier 42A to a selected duplexer of the duplexers 44A. Each of the duplexers can include a transmit filter and receive filter. Any of the filters of the duplexers 44A and 44B can be implemented in accordance with any suitable principles and advantages discussed herein. The switch 45A can couple the selected duplexer of the duplexers 44A to the diplexer 46. The diplexer 46 can combine RF signals provided by the switches 45A and 45B into a carrier aggregation signal that is transmitted by the antenna 47. The diplexer 46 can isolate different frequency bands of a carrier aggregation signal received by the antenna 47. The diplexer 46 is an example of a frequency domain multiplexer. Other frequency domain multiplexers include a triplexer. Carrier aggregation systems that include triplexers can process carrier aggregation signals associated with three carriers. The switches 45A and 45B and selected receive filters of the duplexers 44A and 44B can provide RF signals with the isolated frequency bands to respective receive paths.

FIG. 2B is a schematic diagram of a carrier aggregation system 50. The illustrated carrier aggregation system 50 includes power amplifiers 42A and 42B, low noise amplifiers 52A and 52B, switches 53A and 53B, filters 54A and 54B, diplexer 46, and antenna 47. The power amplifiers 42A and 42B can each transmit an amplified RF signal associated with a different carrier. The switch 53A can be a transmit/receive switch. The switch 53A can couple the filter 54A to an output of the power amplifier 42A in a transmit mode and to an input of the low noise amplifier 52A in a receive mode. The filter 54A and/or the filter 54B can be implemented in accordance with any suitable principles and advantages discussed herein. The diplexer 46 can combine RF signals from the power amplifiers 42A and 42B provided by the switches 53A and 53B into a carrier aggregation signal that is transmitted by the antenna 47. The diplexer 46 can isolate different frequency bands of a carrier aggregation signal received by the antenna 47. The switches 53A and 53B and the filters 54A and 54B can provide RF signals with the isolated frequency bands to respective low noise amplifiers 52A and 52B.

FIG. 2C is a schematic diagram of a carrier aggregation system 60 that includes multiplexers in signal paths between power amplifiers and an antenna. The illustrated carrier aggregation system 60 includes a low band path, a medium band path, and a high band path. In certain implementations, a low band path can process radio frequency signals having a frequency of less than 1 GHz, a medium band path can process radio frequency signals having a frequency between 1 GHz and 2.2 GHz, and a high band path can process radio frequency signals having a frequency above 2.2 GHz.

A diplexer 46 can be included between RF signal paths and an antenna 47. The diplexer 46 can frequency multiplex radio frequency signals that are relatively far away in frequency. The diplexer 46 can be implemented with passive circuit elements having a relatively low loss. The diplexer 46 can combine (for transmit) and separate (for receive) carriers of carrier aggregation signals.

As illustrated, the low band path includes a power amplifier 42A configured to amplify a low band radio frequency signal, a band select switch 43A, and a multiplexer 64A. The band select switch 43A can electrically connect the output of the power amplifier 42A to a selected transmit filter of the multiplexer 64A. The selected transmit filter can be a band pass filter with a pass band corresponding to a frequency of an output signal of the power amplifier 42A. The multiplexer 64A can include any suitable number of transmit filters and any suitable number of receive filters. One or more of the transmit filters and/or one or more of the receive filters can be implemented in accordance with any suitable principles and advantages discussed herein. The multiplexer 64A can have the same number of transmit filters as receive filters. In some instances, the multiplexer 64A can have a different number of transmit filters than receive filters.

As illustrated in FIG. 2C, the medium band path includes a power amplifier 42B configured to amplify a medium band radio frequency signal, a band select switch 43B, and a multiplexer 64B. The band select switch 43B can electrically connect the output of the power amplifier 42B to a selected transmit filter of the multiplexer 64B. The selected transmit filter can be a band pass filter with a pass band corresponding to a frequency of an output signal of the power amplifier 42B. The multiplexer 64B can include any suitable number of transmit filters and any suitable number of receive filters. One or more of the transmit filters and/or one or more of the receive filters can be implemented in accordance with any suitable principles and advantages discussed herein. The multiplexer 64B can have the same number of transmit filters as receive filters. In some instances, the multiplexer 64B can have a different number of transmit filters than receive filters.

In the illustrated carrier aggregation system 60, the high band path includes a power amplifier 42C configured to amplify a high band radio frequency signal, a band select switch 43C, and a multiplexer 64C. The band select switch 43C can electrically connect the output of the power amplifier 42C to a selected transmit filter of the multiplexer 64C. The selected transmit filter can be a band pass filter with a pass band corresponding to a frequency of an output signal of the power amplifier 42C. The multiplexer 64C can include any suitable number of transmit filters and any suitable number of receive filters. One or more of the transmit filters and/or one or more of the receive filters can be implemented in accordance with any suitable principles and advantages discussed herein. The multiplexer 64C can have the same number of transmit filters as receive filters. In some instances, the multiplexer 64C can have a different number of transmit filters than receive filters.

A select switch 65 can selectively provide a radio frequency signal from the medium band path or the high band path to the diplexer 46. Accordingly, the carrier aggregation system 60 can process carrier aggregation signals with either a low band and high band combination or a low band and medium band combination.

FIG. 2D is a schematic diagram of a carrier aggregation system 70 that includes multiplexers in signal paths between power amplifiers and an antenna. The carrier aggregation system 70 is like the carrier aggregation system 60 of FIG. 2C, except that the carrier aggregation system 70 includes switch-plexing features. Switch-plexing can be implemented in accordance with any suitable principles and advantages discussed herein.

Switch-plexing can implement on-demand multiplexing. Some radio frequency systems can operate in a single carrier mode for a majority of time (e.g., about 95% of the time) and in a carrier aggregation mode for a minority of the time (e.g., about 5% of the time). Switch-plexing can reduce loading in a single carrier mode in which the radio frequency system can operate for the majority of the time relative to a multiplexer that includes filters having a fixed connection at a common node. Such a reduction in loading can be more significant when there are a relatively larger number of filters included in multiplexer.

In the illustrated carrier aggregation system 70, duplexers 64B and 64C are selectively coupled to a diplexer 46 by way of a switch 75. The switch 75 is configured as a multi-close switch that can have two or more throws active concurrently. Having multiple throws of the switch 75 active concurrently can enable transmission and/or reception of carrier aggregation signals. The switch 75 can also have a single throw active during a single carrier mode. As illustrated, each duplexer of the duplexer 64B is coupled to a separate throw of the switch 75. Similarly, the illustrated duplexers 64C include a plurality of duplexers coupled to separate throws of the switch 75. Alternatively, instead of duplexers being coupled to each throw the switch 75 as illustrated in FIG. 2D, one or more individual filters of a multiplexer can be coupled to a dedicated throw of a switch coupled between the multiplexer and a common node. For instance, in some implementations, such a switch could have twice as many throws as the illustrated switch 75.

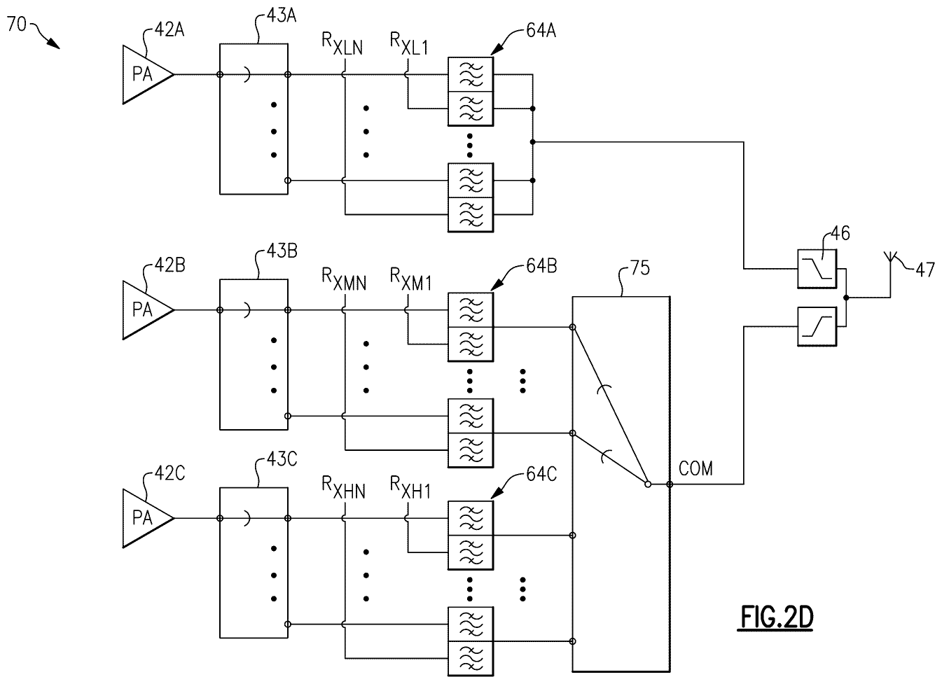

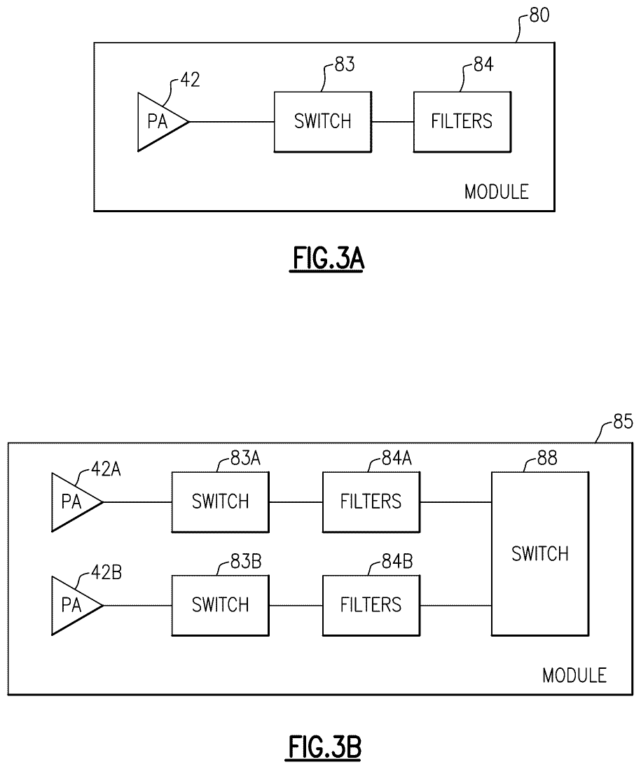

The filters discussed herein can be implemented in a variety of packaged modules. Some example packaged modules will now be discussed in which any suitable principles and advantages of the filters discussed herein can be implemented. FIGS. 3A and 3B are schematic block diagrams of illustrative packaged modules according to certain embodiments.

FIG. 3A is a schematic block diagram of a module 80 that includes a power amplifier 42, a switch 83, and filters 84 in accordance with one or more embodiments. The module 80 can include a package that encloses the illustrated elements. The power amplifier 42, switch 83, and filters 84 can be disposed on the same packaging substrate. The packaging substrate can be a laminate substrate, for example. The switch 83 can be a multi-throw radio frequency switch. The switch 83 can electrically couple an output of the power amplifier 42 to a selected filter of the filters 84. The filters 84 can include any suitable number of surface acoustic wave filters. One or more filters of the filters 84 can be implemented in accordance with any suitable principles and advantages disclosed herein.

FIG. 3B is a schematic block diagram of a module 85 that includes power amplifiers 42A and 42B, switches 83A and 83B, and filters 84A and 84B in accordance with one or more embodiments, and an antenna switch 88. The module 85 is like the module 80 of FIG. 3A, except the module 85 includes an additional RF signal path and the antenna switch 88 arranged to selectively couple a signal from the filters 84A or the filters 84B to an antenna node. One or more filters of the filters 84A and/or 84B can be implemented in accordance with any suitable principles and advantages disclosed herein. The additional RF signal path includes an additional power amplifier 42B, an additional switch 83B, and additional filters 84B. The different RF signal paths can be associated with different frequency bands and/or different modes of operation (e.g., different power modes, different signaling modes, etc.).

In recent years, in the field of information communication devices such as mobile phones, acoustic wave devices having a comb-shaped IDT electrode formed on a surface of a piezoelectric substrate are used as circuit elements such as resonators, filters, and the like.

FIG. 4 shows an example of such an acoustic wave device. In FIG. 4, a plan view of an acoustic wave device 400 is shown. In this description, the acoustic wave device 400 can be also referred to as a resonator. The acoustic wave device 400 is formed by arranging two IDT electrodes 402 and two reflectors 403 on a piezoelectric substrate 401. The IDT electrodes 402 each have a bus bar 411 and a plurality of electrode fingers 412 that extends from the bus bar 411. The respective electrode fingers 412 of each of the IDT electrodes 402 are arranged such that the electrode fingers 412 thereof are arranged interleaved with the respective electrode fingers 412 of the other IDT electrode 402. The reflectors 403 are arranged so as to interpose the IDT electrodes 402 therebetween.

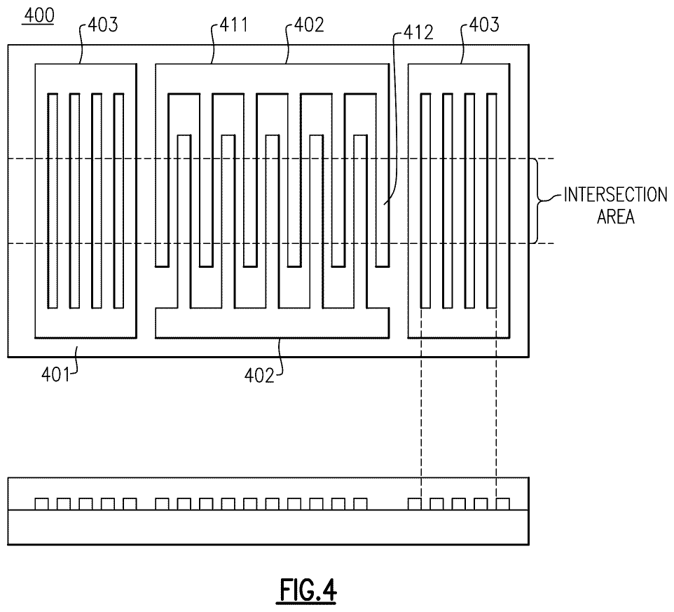

FIG. 5 is a sectional view of the acoustic wave device 500 aligned along a single electrode finger 412. In the acoustic wave device 500, propagation of an acoustic wave is concentrated to the coating film 504, thereby suppressing a high-order transverse mode wave as an unnecessary wave.

In filter design, resonators are the building blocks to achieve the filter response. For example, a combination of resonators can be used for a band pass filter. More specifically, the resonance frequency (Fr) of a shunt resonator is utilized to create the lower rejection edge, and the anti-resonance frequency (Fa) of a series resonator is utilized to create the higher rejection edge.

It is preferred that an electromechanical coupling coefficient (kt2) of a resonator is set to the optimum value so that the filter bandwidth and lower and higher skirt steepness meets the filter's specification. However, sometimes the value of kt2 achieved therethrough is not the optimum value. In such implementations, some other component like an inductor or a capacitor may be used to increase and reduce the value of kt2.

Currently, to meet the desired requirements, one or more of the following schemes can be adopted: (a) The use of a MIM (“metal-insulator-metal”) capacitor, where the insulator can be the passivation layer, like SiO₂; (b) the use of a withdrawn IDT of the resonator; and/or (c) the addition of a lumped element capacitor (SMD cap). For any of the above measures, the quality factor (Q) of such capacitors may be low, and the capacitor's own resonance may negatively impact the filter performance.

When using an IDT capacitor—similar to a resonator, but with the reflectors on both sides removed—there may be some unwanted response above the filter passband due to the high Q at the resonance frequency of the IDT capacitor. Thus, in the present disclosure, an acoustic wave device according to an embodiment is suggested to improve the quality factor of the resonator.

FIG. 6 is a schematic diagram of an example of an acoustic wave device 600 according to an embodiment of the present disclosure. In FIG. 6, the acoustic wave device 600 may include a substrate 602, a pair of interdigital transducer (IDT) electrodes 604, and at least one IDT capacitor 606. According to some implementations, the acoustic wave device 600 may further include reflectors 608-1, 608-2.

The substrate 602 may be a piezoelectric substrate. The substrate 602 may be formed of lithium niobate (LiNbO₃). The pair of IDT electrodes 604 may be disposed on the substrate 602.

The pair of IDT electrodes 604 may be configured to excite a main acoustic wave on the substrate 602. Each of IDT electrodes 602 can be formed of at least one of aluminum (Al), copper (Cu), aluminum-magnesium-copper (AlMgCu) alloy, tungsten (W), platinum (Pt), or molybdenum (Mo).

Each of the IDT electrodes 604 may include a bus bar and a plurality of fingers extending from the bus bar. The plurality of fingers may extend in a first direction perpendicular to a propagation direction of the main acoustic wave generated by the acoustic wave device 600. The respective fingers of one IDT electrode may be arranged interleaved with respective fingers of the other IDT electrode.

At least one IDT capacitor 606 may be disposed on the substrate 602. The at least one IDT capacitor 606 may be disposed apart from the pair of IDT electrodes along the first direction. In FIG. 6, one IDT capacitor 606 is illustrated, but the acoustic wave device 600 may include a plurality of IDT capacitors. For example, the acoustic wave device 600 may include two IDT capacitors, and one IDT capacitor may be disposed on one side of the IDT electrodes 604 and the other IDT capacitor may be disposed on the opposite side of the IDT electrodes 604 along the first direction.

The at least one IDT capacitor 606 may have a similar structure as the IDT electrodes 604. That is, the IDT capacitor 606 may include a pair of bus bars extending along a second direction parallel to the propagation direction of the main acoustic wave. The IDT capacitor 606 may include a predefined number of fingers extending from respective bus bars along the first direction.

The at least one IDT capacitor 606 may have a width (W) in the first direction less than a predetermined value. The width (W) and the length (L) of the IDT capacitor 606 can be determined based on a desired frequency response of the acoustic wave device 600. For example, if the width (W) can be reduced by half, the length (L) of the IDT capacitor 606 may be doubled. The product of the width (W) and the length (L) can be a constant value such that the total capacitance of the IDT capacitor 606 is constant. By adjusting the width of the IDT capacitor 606, the frequency response of the IDT capacitor 606 in a range below a resonance frequency of the IDT capacitor 606 can be controlled.

In determining the width (W) and the length (L) of the IDT capacitor 606, a pitch between the adjacent fingers may be fixed. Therefore, as the length (L) of the IDT capacitor 606 is increased, the number of fingers of the IDT capacitor 606 may also be increased.

According to another embodiment, when determining the width (W) and the length (L) of the IDT capacitor 606, the length (L) can be fixed while the width (W) is adjusted.

According to another embodiment, the at least one IDT capacitor 606 may include a pair of bus bars extending along the first direction. That is, the IDT capacitor 606 may be rotated by 90 degrees with respect to the propagation direction of the main acoustic wave. In this embodiment, at least one IDT capacitor 606 may include a predefined number of fingers extending from respective bus bars along a second direction parallel to the propagation direction of the main acoustic wave.

The acoustic wave device 600 may further include reflectors 608-1, 608-2 formed on the substrate 602. One of the reflectors 608-1 may be adjacent to one side of the pair of IDT electrodes 604 and another reflector 608-2 may be adjacent to the opposite side of the pair of IDT electrodes 604 so as to interpose the pair of IDT electrodes 604 therebetween. The reflectors 608-1, 608-2 and the pair of IDT electrodes 604 may be arranged along a second direction parallel to the propagation direction of the main acoustic wave.

According to embodiments of the present disclosure, the narrower the width (W) of the IDT capacitor 606, the smaller the conductance, i.e., the real part of the admittance Y, and therefore the better a quality factor (Q) in the region below Fs can be achieved.

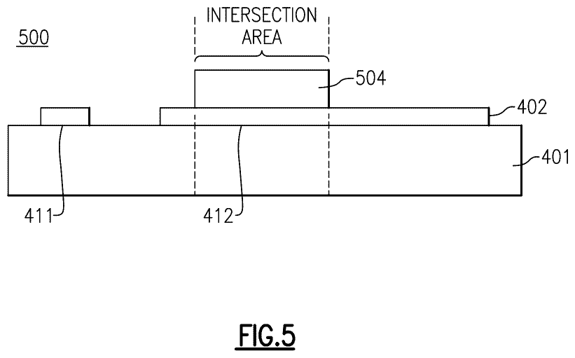

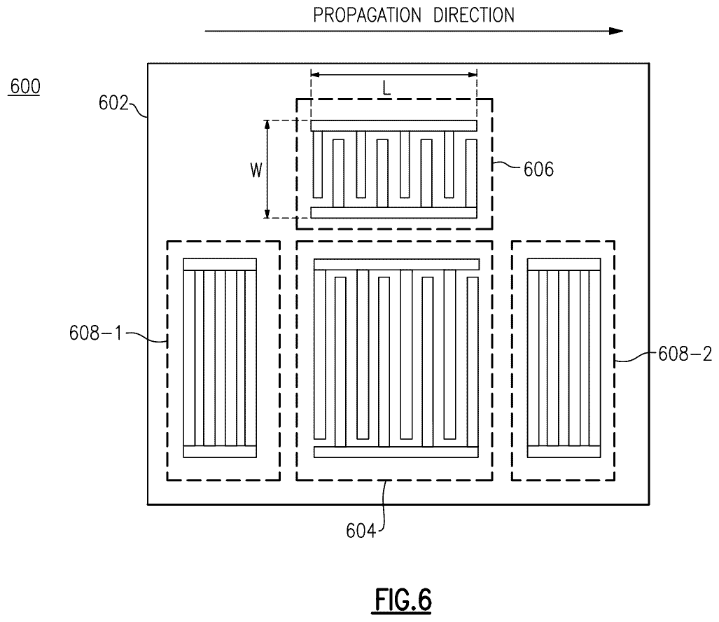

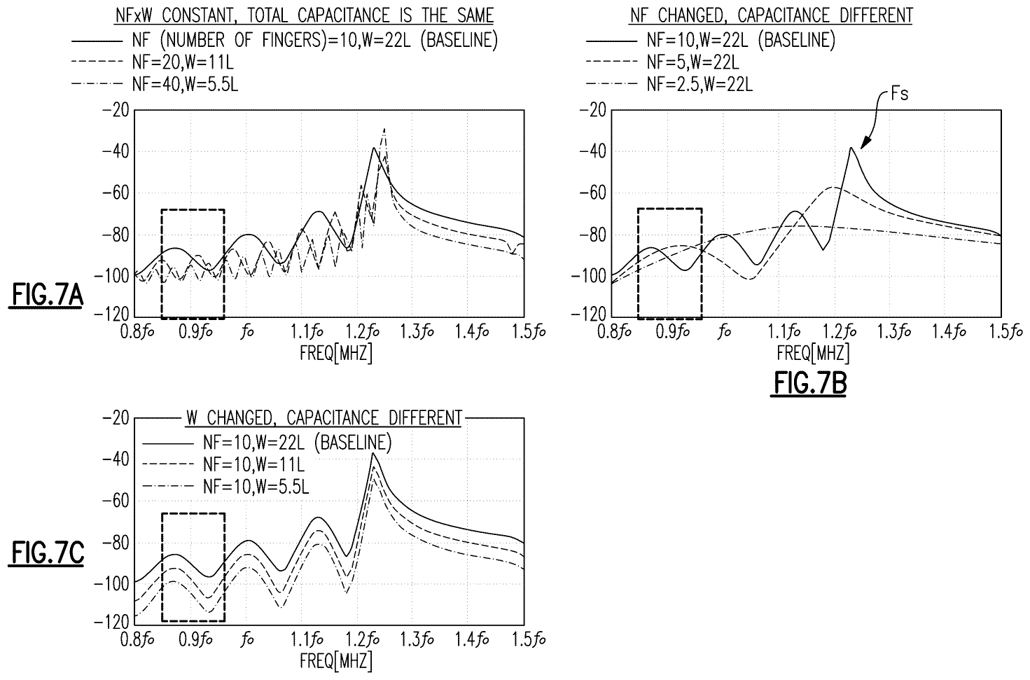

FIG. 7A shows an example of a simulation result of measuring the conductance (i.e., the real part of the admittance Y) of IDT capacitors 606 having constant total capacitance. The dotted box shows the frequency range of the filter of interest. The resonance frequency of the IDT capacitors 606 may be much higher than the frequency range of interest. As can be seen from FIG. 7A, the IDT capacitor 606 having the narrowest width (W) and the largest number of fingers shows the best frequency response in the dotted box.

FIG. 7B shows an example of a simulation result of measuring the conductance (i.e. the real part of the admittance Y) of IDT capacitors 606 having different lengths (L) with fixed widths (W). FIG. 7C shows an example of a simulation result of measuring the conductance (i.e., the real part of the admittance Y) of IDT capacitors 606 having different widths (W) with fixed lengths (L). As can be seen from FIG. 7C, the IDT capacitor 606 with the smallest width (W) shows the best frequency response in the dotted box.

FIG. 8 is a schematic diagram of an example of an acoustic wave device 800 according to an embodiment of the present disclosure. In FIG. 8, the acoustic wave device 800 may include a substrate 802, a pair of interdigital transducer (IDT) 804, and at least one IDT capacitor 806. According to an embodiment, the acoustic wave device 800 may further include reflectors 808-1, 808-2.

The components and structures of the acoustic wave device 800 may be similar to those of the acoustic wave device 600 shown in FIG. 6, except the arrangement of the IDT capacitor 806.

In this embodiment, the acoustic wave device 800 may include at least one IDT capacitor 806 disposed apart from the pair of IDT electrodes 804 along the first direction. That is, the at least one IDT capacitor 806 can be rotated by 90 degrees with respect to the propagation direction of the main acoustic wave, compared to the IDT capacitor 606 shown in FIG. 6. As shown in FIG. 8, and in contrast to the implementation shown in FIG. 6, the IDT capacitor 806 may include a pair of bus bars arranged along the first direction.

According to some embodiments of the present disclosure, the 90 degrees rotation of the IDT capacitor 806 subdues the main mode response which would show as a spike in the filter response. According to some implementations, the pitch can be wider to further improve the quality factor (Q) of the IDT capacitor 806.

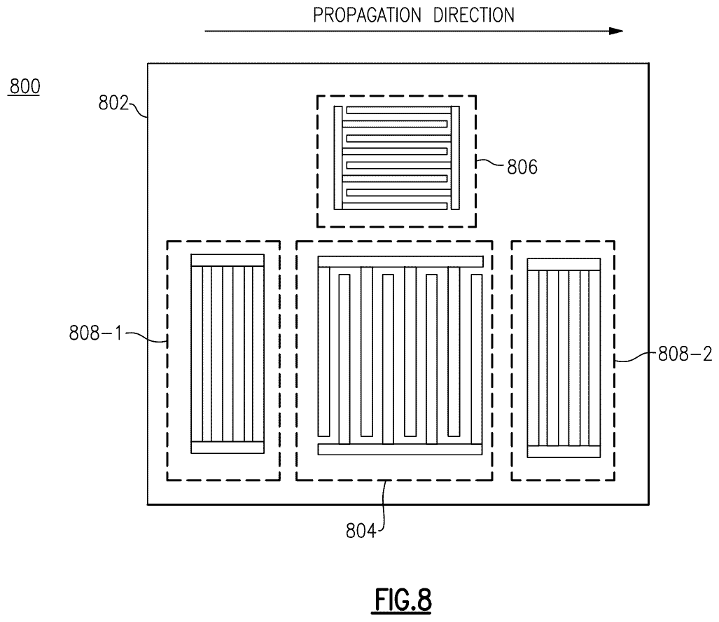

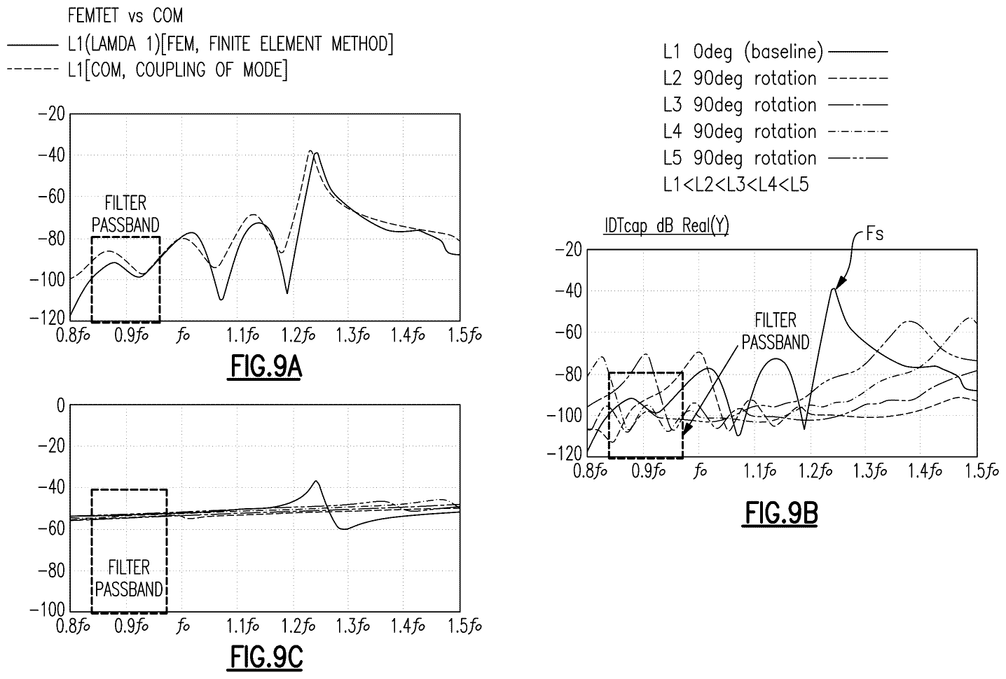

FIG. 9A shows an example of a simulation result of measuring the conductance (i.e., the real part of the admittance Y) of IDT capacitors 806 with different measurement methods. FIG. 9B shows an example of a simulation result of measuring the conductance (i.e., the real part of the admittance Y) of IDT capacitors 806 rotated by 90 degrees with different lengths compared to a non-rotated IDT capacitor. FIG. 9C shows an example of a simulation result of measuring the capacitance of IDT capacitors 806 rotated by 90 degrees compared to a non-rotated IDT capacitor. In these simulations, the main filter IDT pitch is set so that Fs is around 900 MHz, while the IDT capacitor pitch is set so that its Fs is much higher, e.g., 1.2 GHz.

As can be seen from FIGS. 9A-9C, a rotation by 90 degrees will produce a significantly reduced main mode response which would show up as a spike in the filter response. Furthermore, FIG. 9C shows that capacitance value is the same both for 90 degrees rotation and 0 degrees rotation of an IDT capacitor.

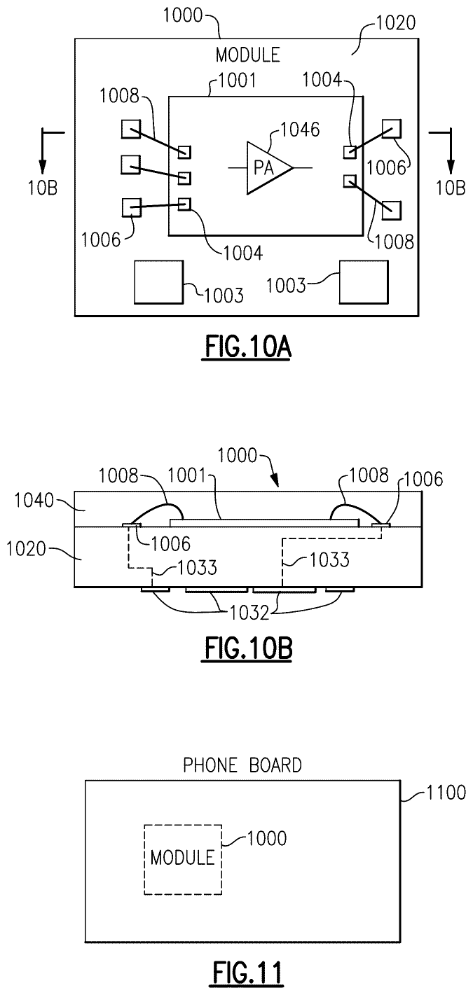

FIG. 10A is a schematic diagram of one embodiment of a packaged module 1000. FIG. 10B is a schematic diagram of a cross-section of the packaged module 1000 of FIG. 10A taken along the lines 10B-10B.

The packaged module 1000 includes an IC or die 1001, surface mount components 1003, wirebonds 1008, a package substrate 1020, and encapsulation structure 1040. The package substrate 1020 includes pads 1006 formed from conductors disposed therein. Additionally, the die 1001 includes pads 1004, and the wirebonds 1008 electrically connect the pads 1004 of the die 1001 to the pads 1006 of the package substrate 1001.

The die 1001 includes a filter module, which can be implemented in accordance with any of the embodiments disclosed herein.

The packaging substrate 1020 can be configured to receive a plurality of components such as the die 1001 and the surface mount components 1003, which can include, for example, surface mount capacitors and/or inductors.

As shown in FIG. 10B, the packaged module 1000 may include a plurality of contact pads 1032 disposed on the side of the packaged module 1000 opposite the side used to mount the die 1001. Configuring the packaged module 1000 in this manner can aid in connecting the packaged module 1000 to a circuit board such as a phone board of a wireless device. The example contact pads 1032 can be configured to provide RF signals, bias signals, power low voltage(s) and/or power high voltage(s) to the die 1001 and/or the surface mount components 1003. As shown in FIG. 10B, the electrically connections between the contact pads 1032 and the die 1001 can be facilitated by connections 1033 through the package substrate 1020. The connections 1033 can represent electrical paths formed through the package substrate 1020, such as connections associated with vias and conductors of a multilayer laminated package substrate.

In some embodiments, the packaged module 1000 can also include one or more packaging structures to, for example, provide protection and/or facilitate handling of the packaged module 1000. Such a packaging structure can include an overmold or encapsulation structure 1040 formed over the packaging substrate 1020 and the components and die(s) disposed thereon.

It will be understood that although the packaged module 1000 is described in the context of electrical connections based on wirebonds, one or more features of the present disclosure can also be implemented in other packaging configurations, including, for example, flip-chip configurations.

FIG. 11 is a schematic diagram of one embodiment of a phone board 1100. The phone board 1100 includes the module 1000 shown in FIGS. 10A and 10B attached thereto. Although not illustrated in FIG. 11 for clarity, the phone board 1100 can include additional components and structures.

Some of the embodiments described above have provided examples in connection with wireless devices or mobile phones. However, the principles and advantages of the embodiments can be used for any other systems or apparatus that have uses for resonators or filters including the resonators.

Such resonators or filters can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to. ” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items covers all of the following interpretations of the word: any of the items in the list, all of the items in the list, and any combination of the items in the list.

Moreover, conditional language used herein, such as, among others, “can,” “could,” “might,” “e.g.,” “for example,” “such as,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments is not intended to be exhaustive or to limit the disclosed embodiments to the precise forms disclosed above. While specific embodiments and examples are described above for illustrative purposes, various equivalent modifications are possible within the scope of the disclosure, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings provided herein can be applied to other systems, not necessarily the systems described above. The elements and acts of the various embodiments described above can be combined to provide further embodiments.

While certain embodiments have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An acoustic wave device comprising:
a substrate;
a pair of interdigital transducer (IDT) electrodes disposed on the substrate, each of the IDT electrodes including a bus bar and a plurality of fingers extending from the bus bar along a first direction perpendicular to a propagation direction of a main acoustic wave, a respective finger of one IDT electrode arranged interleaved with respective fingers of the other IDT electrode; and
at least one IDT capacitor disposed on the substrate and apart from the pair of IDT electrodes along the first direction, the at least one IDT capacitor having a width in the first direction less than a predetermined value such to control a frequency response of the at least one IDT capacitor in a range below a resonance frequency of the at least one IDT capacitor.

2. The acoustic wave device of claim 1 wherein the at least one IDT capacitor includes a pair of bus bars extending along a second direction parallel to the propagation direction of the main acoustic wave.

3. The acoustic wave device of claim 2 wherein the at least one IDT capacitor includes a predefined number of fingers extending from respective bus bars along the first direction.

4. The acoustic wave device of claim 1 wherein the at least one IDT capacitor includes a pair of bus bars extending along the first direction.

5. The acoustic wave device of claim 4 wherein the at least one IDT capacitor includes a predefined number of fingers extending from respective bus bars along a second direction parallel to the propagation direction of the main acoustic wave.

6. The acoustic wave device of claim 1 further comprising reflectors formed on the substrate, one of the reflectors being adjacent to one side of the pair of IDT electrodes and another reflector being adjacent to an opposite side of the pair of IDT electrodes so as to interpose the pair of IDT electrodes therebetween, the reflectors and the pair of IDT electrodes arranged along a second direction parallel to the propagation direction of the main acoustic wave.

7. The acoustic wave device of claim 1 wherein the at least one IDT capacitor includes a pair of bus bars extending along the first direction.

8. The acoustic wave device of claim 7 wherein the at least one IDT capacitor includes a predefined number of fingers extending from respective bus bars along a second direction parallel to the propagation direction of the main acoustic wave.

9. A radio frequency module comprising:
a packaging substrate configured to receive a plurality of components; and
an acoustic wave device implemented on the packaging substrate, the acoustic wave device including a substrate, a pair of interdigital transducer (IDT) electrodes disposed on the substrate, each of the IDT electrodes including a bus bar and a plurality of fingers extending from the bus bar along a first direction perpendicular to a propagation direction of a main acoustic wave, a respective finger of one IDT electrode arranged interleaved with respective fingers of the other IDT electrode, and at least one IDT capacitor disposed on the substrate and apart from the pair of IDT electrodes along the first direction, the at least one IDT capacitor having a width in the first direction less than a predetermined value such to control a frequency response of the at least one IDT capacitor in a range below a resonance frequency of the at least one IDT capacitor.

10. The radio frequency module of claim 9 wherein the radio frequency module is a front-end module.

11. The radio frequency module of claim 9 wherein the at least one IDT capacitor includes a pair of bus bars extending along a second direction parallel to the propagation direction of the main acoustic wave.

12. The radio frequency module of claim 11 wherein the at least one IDT capacitor includes a predefined number of fingers extending from respective bus bars along the first direction.

13. The radio frequency module of claim 9 wherein the at least one IDT capacitor includes a pair of bus bars extending along the first direction.

14. The radio frequency module of claim 13 wherein the at least one IDT capacitor includes a predefined number of fingers extending from respective bus bars along a second direction parallel to the propagation direction of the main acoustic wave.

15. The radio frequency module of claim 9 wherein the acoustic wave device further includes reflectors formed on the substrate, one of the reflectors being adjacent to one side of the pair of IDT electrodes and another reflector being adjacent to an opposite side of the pair of IDT electrodes so as to interpose the pair of IDT electrodes therebetween, the reflectors and the pair of IDT electrodes arranged along a second direction parallel to the propagation direction of the main acoustic wave.

16. A mobile device comprising:
an antenna configured to receive a radio frequency signal; and
a front end system configured to communicate with the antenna, the front end system including an acoustic wave device including a substrate, a pair of interdigital transducer (IDT) electrodes disposed on the substrate, each of the IDT electrodes including a bus bar and a plurality of fingers extending from the bus bar along a first direction perpendicular to a propagation direction of a main acoustic wave, a respective finger of one IDT electrode arranged interleaved with respective fingers of the other IDT electrode, and at least one IDT capacitor disposed on the substrate and apart from the pair of IDT electrodes along the first direction, the at least one IDT capacitor having a width in the first direction less than a predetermined value such to control a frequency response of the at least one IDT capacitor in a range below a resonance frequency of the at least one IDT capacitor.

17. The mobile device of claim 16 wherein the at least one IDT capacitor includes a pair of bus bars extending along a second direction parallel to the propagation direction of the main acoustic wave.

18. The mobile device of claim 17 wherein the at least one IDT capacitor includes a predefined number of fingers extending from respective bus bars along the first direction.

19. The mobile device of claim 16 wherein the at least one IDT capacitor includes a pair of bus bars extending along the first direction.

20. The mobile device of claim 19 wherein the at least one IDT capacitor includes a predefined number of fingers extending from respective bus bars along a second direction parallel to the propagation direction of the main acoustic wave.
